(19) United States
(12) Patent Application Publication
(10) Pub. No.: US 2024/0259708 A1
(43) Pub. Date: Aug. 1, 2024

(54) IMAGING DEVICE

(71) Applicant: Panasonic Intellectual Property Management Co., Ltd., Osaka (JP)

(72) Inventor: MAKOTO SHOUHO, Osaka (JP)

(21) Appl. No.: 18/634,097

(22) Filed: Apr. 12, 2024

Related U.S. Application Data
(63) Continuation of application No. PCT/JP2022/027632, filed on Jul. 14, 2022.

(30) Foreign Application Priority Data
Nov. 8, 2021 (JP) 2021-181831

(51) Int. Cl. H04N 25/709; H04N 25/53; H04N 25/65

(52) U.S. Cl. CPC H04N 25/709; H04N 25/53; H04N 25/65

(57) ABSTRACT

An imaging device includes unit pixel cells arranged in rows and columns and a voltage supply circuit. Each of the unit pixel cells includes a pixel electrode, a counter electrode, a photoelectric conversion layer converting light into signal charge, and a charge accumulation region electrically connected to the pixel electrode to accumulate signal charge. The unit pixel cells form pixel blocks each including one or more rows. The counter electrode is continuous between pixels in each pixel block and is separated between different pixel blocks. The voltage supply circuit sequentially performs a shutter operation on the pixel blocks at different timings. The shutter operation forms an exposure period by applying a first voltage to the counter electrode and forms a non-exposure period by applying a second voltage to the counter electrode.

### BACKGROUND

### 1. Technical Field

The present disclosure relates to an imaging device.

### 2. Description of the Related Art

An image sensor using an embedded photodiode is widely used. There has also been proposed a structure in which, instead of the embedded photodiode, a photoelectric conversion element is placed above a semiconductor substrate (see Japanese Unexamined Patent Application Publication No. 2019-054499). The imaging device described in Japanese Unexamined Patent Application Publication No. 2019-054499 has a photoelectric conversion element including a pixel electrode, a counter electrode, and a photoelectric conversion layer sandwiched therebetween. The signal charge generated in the photoelectric conversion element and collected by the pixel electrode is accumulated in a charge accumulation node. The signal charge accumulated in the charge accumulation node is read out to a vertical signal line as a pixel signal.

An imaging device in which a similar structure is used to provide a global shutter has also been proposed (see International Publication No. WO 2017/094229 and U.S. Patent Application Publication No. 2018/0020171). The imaging devices described in International Publication No. WO 2017/094229 and U.S. Patent Application Publication No. 2018/0020171 perform simultaneous exposure of all pixels by controlling the electric field applied to the photoelectric conversion layer at the same time for all pixels. The entire disclosure of International Publication No. WO 2017/094229 and U.S. Patent Application Publication No. 2018/0020171 is incorporated herein by reference.

### SUMMARY

One non-limiting and exemplary embodiment provides an imaging device that can acquire high quality images with reduced noise generation.

In one general aspect, the techniques disclosed here feature an imaging device including pixels arranged in rows and columns, and a voltage supply circuit. Each of the pixels includes a pixel electrode, a counter electrode facing the pixel electrode, a photoelectric conversion layer located between the pixel electrode and the counter electrode, the photoelectric conversion layer converting light into signal charge, and a charge accumulation region electrically connected to the pixel electrode, the charge accumulation region accumulating the signal charge. The pixels form pixel blocks each including one or more rows. The counter electrode is continuous between pixels in each pixel block and separated between different pixel blocks. The voltage supply circuit sequentially performs a shutter operation on the pixel blocks at different timings. The shutter operation forms an exposure period by applying a first voltage to the counter electrode and forms a non-exposure period by applying a second voltage to the counter electrode.

According to the present disclosure, it is possible to provide an imaging device that can acquire high quality images with reduced noise generation.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic diagram illustrating an exemplary circuit configuration of an imaging device according to Embodiment 1 of the present disclosure;

FIG. 2 is a schematic sectional view illustrating an exemplary device structure of a unit pixel cell of the imaging device according to Embodiment 1 of the present disclosure;

FIG. 3 is a schematic plan view illustrating the relationship between the unit pixel cell and a counter electrode of the imaging device according to Embodiment 1 of the present disclosure;

FIG. 4 is a graph illustrating an example of photocurrent characteristics of a photoelectric conversion layer of the imaging device according to Embodiment 1 of the present disclosure;

FIG. 5 is a diagram for describing an example of the operation of the imaging device according to Embodiment 1 of the present disclosure;

FIG. 6 is a schematic plan view illustrating the relationship between a unit pixel cell and a counter electrode of an imaging device according to Embodiment 2 of the present disclosure;

FIG. 7 is a diagram for describing an example of the operation of the imaging device according to Embodiment 2 of the present disclosure;

FIG. 8 is a diagram for describing an example of the operation of an imaging device according to Embodiment 3 of the present disclosure;

FIG. 9 is a diagram for describing another example of the operation of the imaging device according to Embodiment 3 of the present disclosure;

FIG. 10 is a diagram for describing an example of the operation of an imaging device according to Embodiment 4 of the present disclosure;

FIG. 11 is a diagram for describing another example of the operation of the imaging device according to Embodiment 4 of the present disclosure;

FIG. 12 is a schematic diagram illustrating an exemplary circuit configuration of an imaging device according to Embodiment 5 of the present disclosure;

FIG. 13 is a diagram for describing an example of the operation of the imaging device according to Embodiment 5 of the present disclosure; and

FIG. 14 is a block diagram illustrating an example of an imaging system according to Embodiment 6 of the present disclosure.

### DETAILED DESCRIPTIONS

### Underlying Knowledge Forming Basis of One Aspect of Present Disclosure

The present inventors have found that the following problems arise with the imaging device according to the related art described in the “BACKGROUND” section.

The imaging device described in Japanese Unexamined Patent Application Publication No. 2019-054499 is an imaging device that performs a rolling shutter operation. In an imaging device that performs a rolling shutter operation, an exposure period is started by performing a reset operation, and a readout operation is performed after the end of the exposure period, for example. The reset operation that determines the starting time point of the exposure period is also referred to as a shutter operation. The shutter operation and the readout operation are performed sequentially, row by row. Therefore, a reset operation for one row may be performed in parallel with a reset operation for another row.

In such a case, the operations affect each other, and therefore can be a source of noise. Additionally, a noise cancellation operation may be performed to reduce reset noise associated with the reset operation. In the noise cancellation operation, a current needs to be supplied to the pixel in the target row. The current that flows at this time is a factor of noise for pixels in other rows. Accordingly, noise cannot be reduced sufficiently. Power consumption due to the noise cancellation operation also increases.

Imaging devices described in International Publication No. WO 2017/094229 and U.S. Patent Application Publication No. 2018/0020171 are imaging devices that perform a global shutter operation. In an imaging device that performs a global shutter operation, the exposure period is the same for each row, and thus reset and readout operations cannot be performed on any row during the exposure period. That is, a reset operation for one row cannot be performed in parallel with the exposure period of another row. For this reason, a long exposure period cannot be ensured in one frame period in some cases. In this case, an optimal exposure period cannot be set, which may degrade image quality.

The present inventors have studied the above problems, and have come up with a new configuration that can acquire high quality images with reduced noise generation.

For example, an imaging device according to one aspect of the present disclosure includes pixels arranged in rows and columns, and a voltage supply circuit. Each of the pixels includes a pixel electrode, a counter electrode facing the pixel electrode, a photoelectric conversion layer located between the pixel electrode and the counter electrode, the photoelectric conversion layer converting light into signal charge, and a charge accumulation region electrically connected to the pixel electrode, the charge accumulation region accumulating the signal charge. The pixels form pixel blocks each including one or more rows. The counter electrode is continuous between pixels in each pixel block and separated between different pixel blocks. The voltage supply circuit sequentially performs a shutter operation on the pixel blocks at different timings. The shutter operation forms an exposure period by applying a first voltage to the counter electrode and forms a non-exposure period by applying a second voltage to the counter electrode.

This allows the shutter operation to be achieved by the voltage applied to the counter electrode, so that the noise cancellation operation does not need to be performed. For this reason, the effect on other rows can be reduced and noise generation can be reduced. The power consumption required for the noise cancellation operation can also be reduced.

In addition, the rolling shutter operation is possible in units of pixel blocks, whereby a longer exposure period can be ensured. The increased flexibility in setting the exposure period enables the optimal exposure period setting, thereby reducing the degradation of image quality. Thus, according to the imaging device of this aspect, high quality images with reduced noise generation can be acquired.

For example, each pixel block may include pixels belonging to an identical row.

This allows independent control of the shutter operation for each row, and thus the effect between adjacent rows can be sufficiently reduced.

For example, each pixel block may include pixels belonging to two or more identical rows.

This increases the width of a part of the counter electrode separated for each pixel block, which can lower the resistance. In addition, the parasitic capacitance per unit area of the part of the counter electrode separated for each pixel block can also be reduced. For this reason, the settling time constant for the counter electrode is reduced, which shortens the settling period and speeds up the operation of the imaging device.

For example, a length of the exposure period in a first frame period may be different from a length of the exposure period in a second frame period different from the first frame period.

This enables adjustment of the exposure period according to the amount of incoming light, for example, so that high quality images can be obtained.

For example, the voltage supply circuit may change a voltage value of the first voltage to two or more values in the exposure period.

This enables fine-tuning of sensitivity, expansion of dynamic range or faster operation, for example.

For example, the voltage supply circuit may change a voltage value of the second voltage to two or more values in the non-exposure period.

This enables faster operation, for example.

For example, an imaging device according to one aspect of the present disclosure further includes output signal lines to which signals from the pixels are input. The output signal lines may be arranged for each column.

This can increase the readout speed of the signal charge, thus speeding up the operation of the imaging device.

For example, an imaging device according to one aspect of the present disclosure further includes output signal lines to which signals from the pixels are input. The voltage supply circuit may be configured to not change the voltage applied to the counter electrode of a second pixel block adjacent to a first pixel block of the pixel blocks in a period for pixels belonging to the first pixel block to output a signal to the output signal lines.

This can sufficiently reduce noise that may flow in from adjacent pixels, further enhancing image quality.

For example, the voltage supply circuit may perform the shutter operation two or more times within one frame period.

This enables adjustment of the exposure period according to the amount of incoming light, for example, so that high quality images can be obtained.

Hereinafter, specific embodiments will be described with reference to the drawings.

Note that all of the embodiments described below illustrate comprehensive or specific examples. The numeric values, shapes, materials, components, arrangement of components, connecting modes, steps, order of steps, and the like illustrated in the following embodiments are an example, and are not intended to limit the present disclosure. Of the components in the following embodiments, those not described in the independent claims are described as optional components.

The drawings are schematic diagrams, and are not necessarily strict illustrations. Accordingly, scale and other details are not necessarily the same in each drawing. Additionally, in the drawings, substantially the same components are indicated by the same reference numerals, and redundant descriptions are omitted or simplified.

In the present specification, terms indicating relationships among elements such as parallel or perpendicular, terms indicating the shape of an element such as rectangle, and numerical ranges are not expressions that express only a strict meaning, but are expressions that indicate a substantially equivalent range, such as even including differences of about a few percent.

In the present specification, the terms “above” and “below” do not indicate the upward (vertically upward) and downward (vertically downward) directions in absolute spatial perception, and are terms defined by a relative positional relationship on the basis of the lamination order in a laminated structure. Additionally, the terms “above” and “below” are applied not only when two components are spaced apart from each other and there is another component between the two components, but also when two components are placed in close contact with each other and the two components touch each other.

### Embodiment 1

### Circuit Configuration of Imaging Device

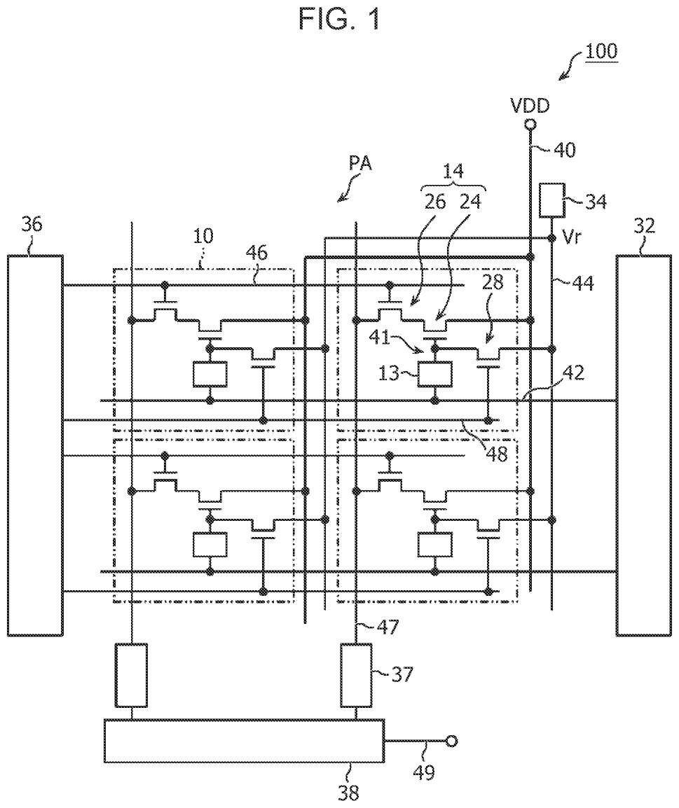

First, a circuit configuration of an imaging device according to Embodiment 1 will be described with reference to FIG. 1. FIG. 1 is a schematic diagram illustrating an exemplary circuit configuration of the imaging device according to the present embodiment.

An imaging device 100 illustrated in FIG. 1 has a pixel array PA including unit pixel cells 10 arranged in rows and columns. FIG. 1 schematically illustrates an example in which four unit pixel cells 10 are arranged in a matrix of two rows and two columns. It goes without saying that the number and arrangement of the unit pixel cells 10 in the imaging device 100 are not limited to the example illustrated in FIG. 1.

Each unit pixel cell 10 is an example of a pixel included in the imaging device 100, and has a photoelectric conversion unit 13 and a signal detection circuit 14. As will be described later with reference to the drawings, the photoelectric conversion unit 13 has a photoelectric conversion layer sandwiched between two electrodes facing each other to receive incident light and generate a signal. The entire photoelectric conversion unit 13 need not be an independent element for each unit pixel cell 10, and a part of the photoelectric conversion unit 13 may be formed across two or more unit pixel cells 10, for example. Details of the specific structure of the photoelectric conversion unit 13 will be described later.

The signal detection circuit 14 is a circuit that detects a signal generated by the photoelectric conversion unit 13. In this example, the signal detection circuit 14 includes a signal detection transistor 24 and an address transistor 26. The signal detection transistor 24 and the address transistor 26 are typically a field effect transistor (FET). Here, an N-channel MOSFET (metal oxide semiconductor field effect transistor) is used as an example of the signal detection transistor 24 and the address transistor 26.

As schematically illustrated in FIG. 1, the control terminal (gate in this example) of the signal detection transistor 24 has an electric connection with the photoelectric conversion unit 13. The signal charge (specifically, holes or electrons) generated by the photoelectric conversion unit 13 is accumulated in a charge accumulation node 41 between the gate of the signal detection transistor 24 and the photoelectric conversion unit 13. The charge accumulation node 41 is also referred to as a floating diffusion node.

The photoelectric conversion unit 13 of each unit pixel cell 10 also has a connection to a sensitivity control line 42. In the configuration illustrated in FIG. 1, the sensitivity control line 42 is connected to a voltage supply circuit 32 included in the imaging device 100.

During operation of the imaging device 100, the voltage supply circuit 32 supplies at least two types of voltages to the photoelectric conversion unit 13 via the sensitivity control line 42 separately to each row. The voltage supply circuit 32 is not limited to a specific power supply circuit, and may be a circuit that generates a predetermined voltage or may be a circuit that converts a voltage supplied from another power supply into a predetermined voltage. As will be described in detail later, by switching the voltage supplied from the voltage supply circuit 32 to the photoelectric conversion unit 13 between voltages that differ from each other for each row, the start and end of accumulation of the signal charge from the photoelectric conversion unit 13 to the charge accumulation node 41 are controlled. In other words, by switching the voltage supplied from the voltage supply circuit 32 to the photoelectric conversion unit 13 for each row, the shutter operation is performed. An example of the operation of the imaging device 100 will be described later.

Each unit pixel cell 10 has a connection to a power supply line 40 that supplies a power supply voltage VDD. As illustrated in FIG. 1, the input terminal (e.g., drain) of the signal detection transistor 24 is connected to the power supply line 40. With the power supply line 40 acting as a source follower power supply, the signal detection transistor 24 amplifies and outputs the signal generated by the photoelectric conversion unit 13.

The input terminal (drain in this example) of the address transistor 26 is connected to the output terminal (source in this example) of the signal detection transistor 24. The output terminal (source in this example) of the address transistor 26 is connected to one of vertical signal lines 47 placed for each column of the pixel array PA. The control terminal (gate in this example) of the address transistor 26 is connected to an address control line 46. By controlling the potential of the address control line 46, the output of the signal detection transistor 24 can be selectively read out to the corresponding vertical signal line 47.

In the example illustrated in FIG. 1, the address control line 46 is connected to a vertical scan circuit 36. The vertical scan circuit 36 is also referred to as a row scan circuit. The vertical scan circuit 36 applies a predetermined voltage to the address control line 46 to select the unit pixel cells 10 placed in each row on a row-by-row basis. As a result, the signal of the selected unit pixel cell 10 is read out.

The vertical signal line 47 is an example of an output signal line that receives input of signals from the unit pixel cells 10, and is a main signal line that transmits pixel signals from the pixel array PA to peripheral circuits. A column signal processing circuit 37 is connected to the vertical signal line 47. The column signal processing circuit 37 is also referred to as a row signal accumulation circuit. The column signal processing circuit 37 performs noise reduction signal processing typified by correlated double sampling (CDS), analog-to-digital conversion (AD conversion), and the like. As illustrated in FIG. 1, the column signal processing circuit 37 is provided for each column of the unit pixel cells 10 in the pixel array PA.

A horizontal signal readout circuit 38 is connected to these column signal processing circuits 37. The horizontal signal readout circuit 38 is also referred to as a column scan circuit. The horizontal signal readout circuit 38 sequentially reads out signals from the column signal processing circuits 37 to a horizontal common signal line 49.

In the configuration exemplified in FIG. 1, the unit pixel cell 10 has a reset transistor 28. As in the signal detection transistor 24 and the address transistor 26, the reset transistor 28 can be a field effect transistor. Hereinafter, unless otherwise noted, an example will be described in which an N-channel MOSFET is applied as the reset transistor 28. As illustrated in FIG. 1, the reset transistor 28 is connected between a reset voltage line 44 that supplies a reset voltage Vr and the charge accumulation node 41. The control terminal (gate in this example) of the reset transistor 28 is connected to a reset control line 48. By controlling the potential of the reset control line 48, the potential of the charge accumulation node 41 can be reset to the reset voltage Vr. In this example, the reset control line 48 is connected to the vertical scan circuit 36. Accordingly, the vertical scan circuit 36 can apply a predetermined voltage to the reset control line 48 to reset the unit pixel cells 10 placed in each row on a row-by-row basis.

In this example, the reset voltage line 44 that supplies the reset voltage Vr to the reset transistor 28 is connected to a reset voltage source 34. The reset voltage source 34 is also referred to as a reset voltage supply circuit. The reset voltage source 34 only needs to have a configuration capable of supplying the predetermined reset voltage Vr to the reset voltage line 44 during operation of the imaging device 100, and, as in the voltage supply circuit 32 described above, is not limited to a specific power supply circuit. Each of the voltage supply circuit 32 and the reset voltage source 34 may be a part of a single voltage supply circuit, or may be independent and separate voltage supply circuits. Note that one or both of the voltage supply circuit 32 and the reset voltage source 34 may be a part of the vertical scan circuit 36. Alternatively, the sensitivity control voltage from the voltage supply circuit 32 and/or the reset voltage Vr from the reset voltage source 34 may be supplied to each unit pixel cell 10 via the vertical scan circuit 36.

In a case where holes are used as the signal charge, ground of the signal detection circuit 14 can be used as the reset voltage Vr. In this case, the voltage supply circuit (not illustrated in FIG. 1) that supplies ground to each unit pixel cell 10 and the reset voltage source 34 can be shared. Moreover, since the power supply line 40 and the reset voltage line 44 can be shared, wiring in the pixel array PA can be simplified. Note, however, that using different voltages for the reset voltage Vr and ground of the signal detection circuit 14 enables more flexible control of the imaging device 100.

### Device Structure of Unit Pixel Cell

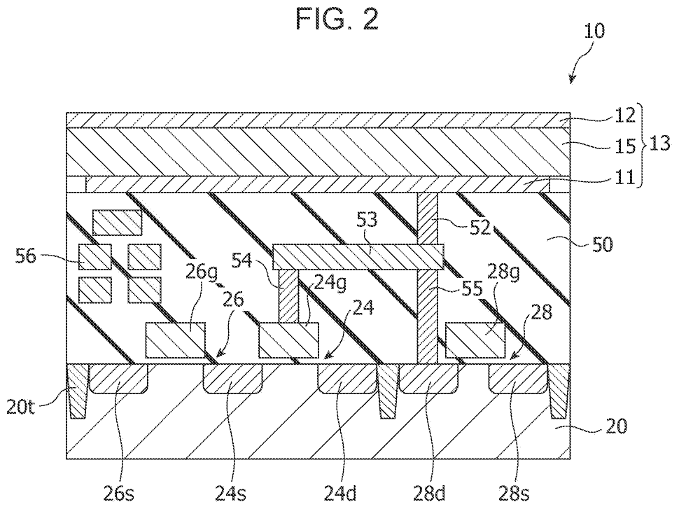

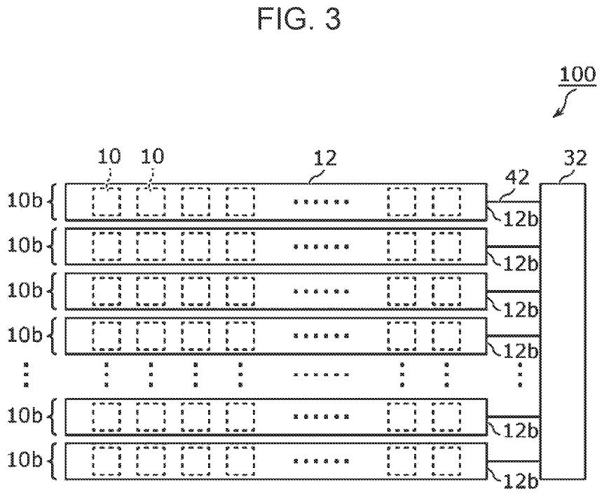

Next, a device structure of the unit pixel cell 10 will be described with reference to FIGS. 2 and 3.

FIG. 2 is a schematic sectional view illustrating an exemplary device structure of the unit pixel cell 10 of the imaging device 100 according to the present embodiment. FIG. 3 is a schematic plan view illustrating the relationship between the unit pixel cell 10 and a counter electrode 12 of the imaging device 100 according to the present embodiment.

In the configuration exemplified in FIG. 2, the signal detection transistor 24, the address transistor 26, and the reset transistor 28 described above are formed on a semiconductor substrate 20. The semiconductor substrate 20 is not limited to a substrate that is a semiconductor in its entirety. The semiconductor substrate 20 may be an insulating substrate in which a semiconductor layer is provided on a surface on the side where a photosensitive region is formed. Here, an example will be described in which a P-type silicon (Si) substrate is used as the semiconductor substrate 20.

The semiconductor substrate 20 has impurity regions (N-type regions in this example) 26s, 24s, 24d, 28d, and 28s, and an element separation region 20t for electrically separating the unit pixel cells 10. Here, the element separation region 20t is also provided between the impurity region 24d and the impurity region 28d. The element separation region 20t is formed, for example, by ion implantation of acceptors under predetermined implantation conditions.

The impurity regions 26s, 24s, 24d, 28d, and 28s are typically a diffusion layer formed in the semiconductor substrate 20. As schematically illustrated in FIG. 2, the signal detection transistor 24 includes the impurity regions 24s and 24d, and a gate electrode 24g. The gate electrode 24g is a polysilicon electrode, for example. The impurity region 24s functions as the source region of the signal detection transistor 24, for example. The impurity region 24d functions as the drain region of the signal detection transistor 24, for example. The channel region of the signal detection transistor 24 is formed between the impurity region 24s and the impurity region 24d.

Similarly, the address transistor 26 includes the impurity regions 26s and 24s, and a gate electrode 26g connected to the address control line 46 illustrated in FIG. 1. The gate electrode 26g is a polysilicon electrode, for example. In this example, the signal detection transistor 24 and the address transistor 26 share the impurity region 24s to be electrically connected to each other. The impurity region 26s functions as the source region of the address transistor 26, for example. The impurity region 26s has a connection to the vertical signal line 47 illustrated in FIG. 1.

The reset transistor 28 includes the impurity regions 28d and 28s, and a gate electrode 28g connected to the reset control line 48 illustrated in FIG. 1. The gate electrode 28g is a polysilicon electrode, for example. The impurity region 28s functions as the source region of the reset transistor 28, for example. The impurity region 28s has a connection to the reset voltage line 44 illustrated in FIG. 1.

On the semiconductor substrate 20, an interlayer insulation layer 50 is placed to cover the signal detection transistor 24, the address transistor 26, and the reset transistor 28. The interlayer insulation layer 50 is formed using an insulating material such as silicon oxide, silicon nitride, or tetraethyl orthosilicate (TEOS). As illustrated in FIG. 2, a wiring layer 56 can be placed in the interlayer insulation layer 50. The wiring layer 56 is typically formed of a metal such as copper, and can include, as a part thereof, wiring such as the vertical signal line 47 described above, for example. Any number of insulating layers in the interlayer insulation layer 50 and any number of layers in the wiring layer 56 placed in the interlayer insulation layer 50 can be set, and are not limited to the example illustrated in FIG. 2.

The photoelectric conversion unit 13 described above is placed on the interlayer insulation layer 50. In other words, in the present embodiment, the unit pixel cells 10 forming the pixel array PA are formed on the semiconductor substrate 20. The unit pixel cells 10 arranged two-dimensionally on the semiconductor substrate 20 form a photosensitive region. The photosensitive region is also referred to as a pixel region. The distance between two adjacent unit pixel cells 10 (i.e., pixel pitch) can be about 2 μm, for example.

The photoelectric conversion unit 13 includes a pixel electrode 11, the counter electrode 12, and a photoelectric conversion layer 15 placed therebetween. In this example, the counter electrode 12 and the photoelectric conversion layer 15 are formed across two or more unit pixel cells 10.

The pixel electrode 11 is provided for each unit pixel cell 10, and is spatially separated from the pixel electrode 11 of another adjacent unit pixel cell 10 to be electrically isolated from the pixel electrode 11 of the other unit pixel cell 10.

By controlling the potential of the counter electrode 12 relative to the potential of the pixel electrode 11, one of the holes or electrons in the hole-electron pairs generated in the photoelectric conversion layer 15 by photoelectric conversion can be collected by the pixel electrode 11. For example, when holes are to be used as the signal charge, the potential of the counter electrode 12 can be set higher than that of the pixel electrode 11 to selectively collect holes by the pixel electrode 11. Hereinafter, a case where holes are used as the signal charge will be used as an example Electrons can be used as the signal charge, as a matter of course.

When an appropriate bias voltage is applied between the counter electrode 12 and the pixel electrode 11, the pixel electrode 11 facing the counter electrode 12 collects one of the positive and negative charges generated by photoelectric conversion in the photoelectric conversion layer 15. The pixel electrode 11 is formed of a metal such as aluminum or copper, metal nitride, polysilicon doped with impurities to add conductivity, or the like.

The pixel electrode 11 may be a light-shielding electrode. For example, by forming a TaN electrode with a thickness of 100 nm as the pixel electrode 11, sufficient light shielding can be achieved. By using a light-shielding electrode as the pixel electrode 11, it is possible to reduce incidence of light having passed the photoelectric conversion layer 15 into the channel region or the impurity region of the transistor formed on the semiconductor substrate 20. Note that the transistor formed on the semiconductor substrate 20 is at least one of the signal detection transistor 24, the address transistor 26, or the reset transistor 28, for example.

A light-shielding film may be formed in the interlayer insulation layer 50 by using the wiring layer 56 described above. By reducing incidence of light into the channel region of the transistor formed on the semiconductor substrate 20, shifting of a characteristic of the transistor such as fluctuation in the threshold voltage can be reduced. Additionally, by reducing incidence of light into the impurity region formed in the semiconductor substrate 20, it is possible to reduce noise due to unintended photoelectric conversion in the impurity region. As described above, reducing incidence of light into the semiconductor substrate 20 contributes to improvement of reliability of the imaging device 100.

As schematically illustrated in FIG. 2, the pixel electrode 11 is connected to the gate electrode 24g of the signal detection transistor 24 via a plug 52, wiring 53, and a contact plug 54. In other words, the gate of the signal detection transistor 24 has an electric connection with the pixel electrode 11. The plug 52 and the wiring 53 are formed of a metal such as copper. The plug 52, the wiring 53, and the contact plug 54 form at least a part of the charge accumulation node 41 (see FIG. 1) between the signal detection transistor 24 and the photoelectric conversion unit 13. The wiring 53 can be a part of the wiring layer 56. Additionally, the pixel electrode 11 is also connected to the impurity region 28d via the plug 52, the wiring 53, and a contact plug 55. In the configuration illustrated in FIG. 2, the gate electrode 24g of the signal detection transistor 24, the plug 52, the wiring 53, the contact plugs 54 and 55, and the impurity region 28d which is one of the source region and the drain region of the reset transistor 28 function as a charge accumulation region for accumulating the signal charge collected by the pixel electrode 11.

By collecting the signal charge by the pixel electrode 11, a voltage corresponding to the amount of signal charge accumulated in the charge accumulation region is applied to the gate of the signal detection transistor 24. The signal detection transistor 24 amplifies the voltage. The voltage amplified by the signal detection transistor 24 is selectively read out as a signal voltage via the address transistor 26.

The counter electrode 12 is typically a transparent electrode formed of a transparent conductive material. The counter electrode 12 is placed on the side of the photoelectric conversion layer 15 on which light is incident. Accordingly, light transmitted through the counter electrode 12 enters the photoelectric conversion layer 15. Note that the light detected by the imaging device 100 is not limited to light within the wavelength range of visible light (e.g., greater than or equal to 380 nm and less than or equal to 780 nm). “Transparent” in the present specification means transmitting at least a part of light in the wavelength range to be detected, and it is not essential to transmit light over the entire wavelength range of visible light. In the present specification, electromagnetic waves in general, including infrared and ultraviolet rays, are referred to as “light” for convenience. Transparent conducting oxide (TCO) such as ITO, IZO, AZO, FTO, SnO₂, TiO₂, and ZnO₂ can be used as the counter electrode 12.

In the present embodiment, as illustrated in FIG. 3, the counter electrode 12 is continuous between unit pixel cells 10 in the same pixel block 10b, and is separated between different pixel blocks 10b. Here, each pixel block 10b includes unit pixel cells 10 belonging to the same row. In other words, the unit pixel cells 10 form pixel blocks 10b each including one row.

The counter electrode 12 has electrode pieces 12b corresponding one-to-one with the pixel blocks 10b. The electrode pieces 12b are provided for respective rows, and are separated from each other. Each electrode piece 12b has a rectangular shape long in the row direction. For example, the electrode piece 12b covers the pixel electrodes 11 of unit pixel cells 10 belonging to the same row. An insulating layer may be placed between adjacent electrode pieces 12b.

As has been described with reference to FIG. 1, the counter electrode 12 has a connection to the sensitivity control line 42 connected to the voltage supply circuit 32. The sensitivity control line 42 is provided for each electrode piece 12b. Accordingly, for each electrode piece 12b, it is possible to collectively apply a sensitivity control voltage of a desired magnitude from the voltage supply circuit 32 to unit pixel cells 10 belonging to a corresponding pixel block 10b via a corresponding sensitivity control line 42.

As will be described in detail later, the voltage supply circuit 32 supplies different voltages in an exposure period and a non-exposure period to each electrode piece 12b of the counter electrode 12. In the present specification, “exposure period” means a period for accumulating, in the charge accumulation region, the signal charge which is one of the positive and negative charges generated by photoelectric conversion, and may be referred to as “charge accumulation period.” Additionally, in the present specification, a period during which the imaging device is operating other than the exposure period is referred to as “non-exposure period.” Note that “non-exposure period” is not limited to a period during which light incidence into the photoelectric conversion unit 13 is blocked, and may include a period during which the photoelectric conversion unit 13 is irradiated with light. Moreover, “non-exposure period” includes a period during which the signal charge is unintentionally accumulated in the charge accumulation region due to parasitic sensitivity. In the present embodiment, the voltage supply circuit 32 can apply voltage independently to each electrode piece 12b. For this reason, both “exposure period” and “non-exposure period” can be set for each electrode piece 12b, that is, for each pixel block 10b.

The photoelectric conversion layer 15 is located between the pixel electrode 11 and the counter electrode 12 to convert light into signal charge. Specifically, the photoelectric conversion layer 15 generates a hole-electron pair by receiving incoming light. One of the generated hole and electron is the signal charge.

The photoelectric conversion layer 15 is formed of an organic material, for example. An organic material is an organic semiconductor material, for example. As an organic semiconductor material, materials including tin naphthalocyanine which has an absorption wavelength in the near-infrared region can be used, for example, but the material is not limited thereto. As the photoelectric conversion layer 15, one or more types of photoelectric conversion materials having an absorption wavelength in a desired wavelength region can be used.

For example, the photoelectric conversion layer 15 may include a p-type semiconductor layer, an n-type semiconductor layer, and a mixed layer located between p-type and n-type semiconductor layers. The p-type semiconductor layer is formed using a donor organic material. The n-type semiconductor layer is formed using an acceptor organic semiconductor material. The mixed layer is a bulk heterojunction layer of p-type and n-type semiconductors, for example. A bulk heterojunction layer is described in detail in Japanese Patent No. 5553727, for example, and the entire disclosure of Japanese Patent No. 5553727 is incorporated herein by reference.

The photoelectric conversion layer 15 may include one or more functional layers other than the layer formed using the photoelectric conversion material. For example, the photoelectric conversion layer 15 may include, as a functional layer, at least one of a hole block layer, an electron block layer, a hole transport layer, or an electron transport layer.

Note that the photoelectric conversion layer 15 may be provided separately for each predetermined region, similarly to the counter electrode 12. For example, the photoelectric conversion layer 15 may be provided separately for each unit pixel cell 10 or for each electrode piece 12b.

### Photocurrent Characteristics of Photoelectric Conversion Layer

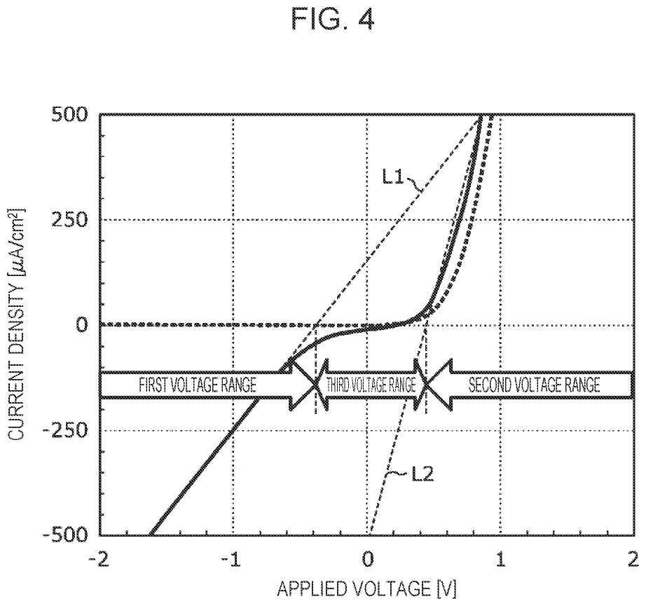

Subsequently, photocurrent characteristics of the photoelectric conversion layer will be described with reference to FIG. 4.

FIG. 4 is a graph illustrating an example of photocurrent characteristics of the photoelectric conversion layer 15 of the imaging device 100 according to the present embodiment. In FIG. 4, the graph in a thick solid line indicates an exemplary current-voltage characteristic (I-V characteristic) of the photoelectric conversion layer 15 under light irradiation. Note that FIG. 4 also illustrates an example of the I-V characteristic in the absence of light irradiation with a thick dashed line.

FIG. 4 illustrates the change in current density between two main surfaces of the photoelectric conversion layer 15 when the bias voltage applied between the main surfaces is varied under a constant illumination. In the present specification, the forward and reverse directions in bias voltage are defined as follows. When the photoelectric conversion layer 15 has a junction structure of a layered p-type semiconductor and a layered n-type semiconductor, a bias voltage that causes the p-type semiconductor layer to have a higher potential than the n-type semiconductor layer is defined as the forward bias voltage. On the other hand, a bias voltage that causes the p-type semiconductor layer to have a lower potential than the n-type semiconductor layer is defined as the reverse bias voltage.

As in the case of using the inorganic semiconductor material, the forward and reverse directions can be defined in a case where an organic semiconductor material is used. When the photoelectric conversion layer 15 has a bulk heterojunction structure, as indicated in Japanese Patent No. 5553727 described above, of the two main surfaces of the bulk heterojunction structure facing the electrodes, one surface shows more p-type semiconductors than n-type semiconductors, and the other surface shows more n-type semiconductors than p-type semiconductors. Accordingly, a bias voltage that causes the main surface side showing more p-type semiconductors than n-type semiconductors to have a higher potential than the main surface side showing more n-type semiconductors than p-type semiconductors is defined as the forward bias voltage.

As illustrated in FIG. 4, the photocurrent characteristics of the photoelectric conversion layer 15 can be generally characterized by three voltage ranges. A first voltage range is a reverse bias voltage range, and is a voltage range in which the absolute value of the output current density increases as the reverse bias voltage increases. The first voltage range may be said to be a voltage range in which the photocurrent increases as the bias voltage applied between the main surfaces of the photoelectric conversion layer 15 increases. A second voltage range is a forward bias voltage range, and is a voltage range in which the output current density increases as the forward bias voltage increases. That is, the second voltage range is a voltage range in which the forward current increases as the bias voltage applied between the main surfaces of the photoelectric conversion layer 15 increases. A third voltage range is a voltage range between the first voltage range and the second voltage range.

The first voltage range, the second voltage range, and the third voltage range can be distinguished by the slope of the photocurrent characteristic graph when using linear vertical and horizontal axes. For reference, in FIG. 4, the average slopes of the graphs in the first and second voltage ranges are indicated by dashed lines L1 and L2, respectively. As illustrated in FIG. 4, the rate of change of the output current density with respect to the increase in the bias voltage in the first, second, and third voltage ranges are different from each other. The third voltage range is defined as a voltage range in which the rate of change of the output current density with respect to the bias voltage is smaller than the rate of change in the first voltage range and the second voltage range. Alternatively, the third voltage range may be defined on the basis of the position of the rising (falling) edge in the graph indicating the I-V characteristic. The third voltage range is typically larger than −1 V and smaller than +1 V. In the third voltage range, there is substantially no change in the current density between the main surfaces of the photoelectric conversion layer 15 even when the bias voltage is varied. As exemplified in FIG. 4, in the third voltage range, the absolute value of the current density is typically less than or equal to 100 μA/cm².

### Operation Example of Imaging Device 100]

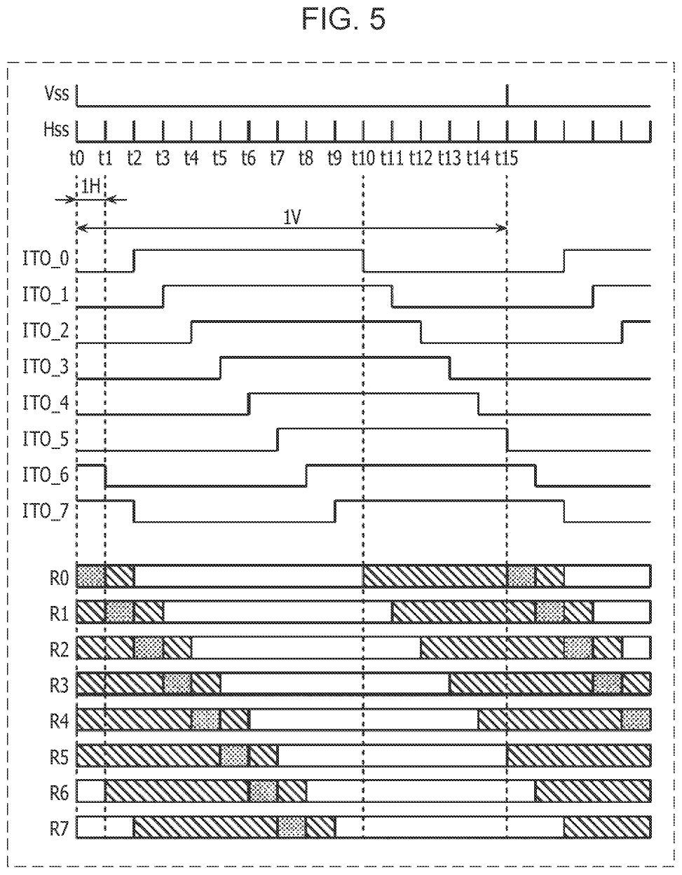

Subsequently, an example of the operation of the imaging device 100 will be described using FIG. 5, referring to FIGS. 1 to 4 as appropriate. For simplicity, the following description will illustrate an example of the operation when the number of rows of the unit pixel cells 10 in the pixel array PA is a total of eight rows including rows R0 to R7.

FIG. 5 is a diagram for describing an example of the operation of the imaging device 100 according to the present embodiment. FIG. 5 illustrates the timing of the falling or rising edge of synchronization signals together with the temporal change in the magnitude of the bias voltage applied to the photoelectric conversion layer 15 and the timing of the reset and exposure in each row of the pixel array PA.

More specifically, the top graph in FIG. 5 indicates the timing of the falling or rising edge of a vertical synchronization signal Vss. The second graph from the top indicates the timing of the falling or rising edge of a horizontal synchronization signal Hss. The pulse interval of the horizontal synchronization signal Hss is one horizontal period represented by 1H. The pulse interval of the vertical synchronization signal Vss is one vertical period represented by 1V. One vertical period corresponds to one frame period.

Below these graphs, graphs represented by ITO_0 to ITO_7 indicate an example of the temporal change of a bias voltage Vb applied from the voltage supply circuit 32 to the corresponding electrode piece 12b of the counter electrode 12 via the sensitivity control line 42. Each of ITO_0 to ITO_7 can be regarded as the electrode piece 12b provided for each pixel block 10b.

Further, the chart below, represented by R0 to R7, schematically indicate the reset and exposure timings for each row of the pixel array PA. Specifically, R0 to R7 indicate the operation of the unit pixel cells 10 belonging to the pixel blocks 10b corresponding to ITO_0 to ITO_7, respectively. For example, R0 indicates the operation of the unit pixel cells 10 belonging to row R0 of the pixel array PA, and the operation of R0 is controlled by the change in voltage indicated by ITO_0.

The chart represented by R0 to R7 indicates the contents of the operation according to the presence/absence and type of shading in the rectangular frame. Specifically, an unshaded white rectangle represents an exposed state. That is, a period occupied by a white rectangle (hereinafter simply described as “white period”) is an exposure period of the unit pixel cells 10 belonging to a corresponding row. Both a rectangle with diagonal shading and a rectangle with dot shading represent a non-exposed state. That is, a period occupied by a rectangle with diagonal shading or a rectangle with dot shading is a non-exposure period of the unit pixel cells 10 belonging to the corresponding row. Of these periods, the period occupied by a rectangle with dot shading (hereinafter simply described as “dot period”) is a period during which the signal readout, reset and reset readout of the unit pixel cells 10 belonging to the corresponding row are performed. That is, the dot period is the sum of a readout period during which signal readout is performed, and a reset period during which reset and readout after reset of the charge accumulation region is performed.

In the present embodiment, the voltage supply circuit 32 performs a shutter operation at different timings for each pixel block 10b. A shutter operation is an operation of forming an exposure period and a non-exposure period. The voltage supply circuit 32 applies a first voltage to the counter electrode 12 to form an exposure period. The first voltage is a voltage included in the first voltage range in FIG. 4, for example. The voltage supply circuit 32 also applies a second voltage to the counter electrode 12 to form a non-exposure period. The second voltage is a voltage included in the third voltage range in FIG. 4, for example.

In image acquisition, first, the charge accumulation region of each unit pixel cell 10 in the pixel array PA is reset. For example, as illustrated in FIG. 5, on the basis of the vertical synchronization signal Vss, at time t0, reset of unit pixel cells 10 belonging to row R0 is started. Note that if exposure is performed in an immediately preceding frame, the pixel signal is read out before the reset, and a post-reset signal (i.e., reset signal) is also read out after the reset.

In resetting the unit pixel cells 10 belonging to row R0, the address transistor 26 whose gate is connected to the address control line 46 is turned on by controlling the potential of the address control line 46 of row R0. Further, the reset transistor 28 whose gate is connected to the reset control line 48 is turned on by controlling the potential of the reset control line 48 of row R0. As a result, the charge accumulation node 41 and the reset voltage line 44 are connected and the reset voltage Vr is supplied to the charge accumulation region. That is, the potential of the gate electrode 24g of the signal detection transistor 24 and the pixel electrode 11 of the photoelectric conversion unit 13 is reset to the reset voltage Vr. Thereafter, the pixel signal after the reset is read out from the unit pixel cells 10 of row R0 via the vertical signal line 47. The pixel signal obtained at this time is a pixel signal corresponding to the magnitude of the reset voltage Vr. After the readout of the pixel signal, the reset transistor 28 and the address transistor 26 are turned off.

In the present embodiment, as schematically illustrated in FIG. 5, pixels belonging to rows R0 to R7 are sequentially reset on a row-by-row basis according to the horizontal synchronization signal Hss. Hereinafter, the interval between pulses of the horizontal synchronization signal Hss, in other words, the period between the selection of one row and the selection of the next row, is sometimes referred to as “1H period.” In this example, the period from time t0 to time t1 corresponds to the 1H period.

For example, focus on row R0. During the period from time t1 to time t2, a voltage V3 is applied from the voltage supply circuit 32 to the electrode piece 12b of the counter electrode 12 such that the potential difference between the pixel electrode 11 and the counter electrode 12 becomes the third voltage range described above. That is, during the period from time t1 after the end of the reset to time t2 at the start of the exposure period, the photoelectric conversion layer 15 of the photoelectric conversion unit 13 is in a state where the bias voltage of the third voltage range is applied.

In the state where the bias voltage of the third voltage range is applied to the photoelectric conversion layer 15, there is substantially no signal charge transfer from the photoelectric conversion layer 15 to the charge accumulation region. This is assumed to be because, in the state where the bias voltage of the third voltage range is applied to the photoelectric conversion layer 15, most of the positive and negative charge generated by light irradiation recombine quickly and disappear before being collected by the pixel electrode 11. Accordingly, in the state where the bias voltage of the third voltage range is applied to the photoelectric conversion layer 15, there is substantially no accumulation of signal charge in the charge accumulation region even if light is incident on the photoelectric conversion layer 15. Therefore, unintended sensitivity during periods other than the exposure period is reduced. Note that unintended sensitivity is also referred to as parasitic sensitivity. As described above, by setting the bias voltage to the photoelectric conversion layer 15 to the third voltage range, the sensitivity can be quickly reduced to zero. When the bias voltage is set to the third voltage range, the signal charge is not collected by the pixel electrode 11, which is the same as no exposure. The period during which the bias voltage is set to the third voltage range is a non-exposure period, as illustrated in FIG. 5. Note that while the voltage V3 for applying the bias voltage of the third voltage range is 0 V as an example, the voltage V3 is not limited to 0 V. The voltage V3 is an example of the second voltage and is the voltage for forming a non-exposure period.

At time t2, the voltage applied to the electrode piece 12b corresponding to ITO_0 is switched to a voltage Ve different from the voltage V3 to start an exposure period. The exposure period is started by the voltage supply circuit 32 switching the voltage applied to the electrode piece 12b of the counter electrode 12 to the voltage Ve different from the voltage V3. The voltage Ve is an example of the first voltage, and is a voltage for forming an exposure period. The voltage Ve is, for example, a voltage that sets the potential difference between the pixel electrode 11 and the counter electrode 12 to the first voltage range described above. The voltage Ve is about 10 V, for example. By applying the voltage Ve to the counter electrode 12, the signal charge (holes in this example) in the photoelectric conversion layer 15 is collected by the pixel electrode 11 and accumulated in the charge accumulation region.

When the voltage supply circuit 32 switches the voltage applied to the electrode piece 12b corresponding to ITO_0 to the voltage V3 again at time t10, the exposure period ends. As described above, in the present embodiment, the voltage applied to the electrode piece 12b of the counter electrode 12 is switched between the voltage V3 and the voltage Ve to switch between an exposure period and a non-exposure period. As can be seen from FIG. 5, the start and end of an exposure period in this example is done sequentially at different timings for respective rows included in the pixel array PA. That is, a voltage is sequentially applied to the electrode pieces 12b forming the counter electrode 12 at different timings for respective rows.

Additionally, the exposure period can be freely selected from the 1H period to almost a 1V period (specifically, a period of 1V to 1H), excluding the period of the readout operation. For example, the execution of the readout operation may be avoided immediately after a change in the voltage applied to the electrode piece 12b, so that fluctuation in the voltage of the electrode piece 12b does not affect the readout operation. A change in the voltage is, for example, a change in the voltage level from Hi to Low or from Low to Hi. The voltage level Hi is the voltage Ve described above, and the voltage level Low is the voltage V3 described above.

In the present embodiment, the signal readout operation is performed after a certain period has elapsed since the change in the voltage applied to the electrode piece 12b. While the certain period is a 5H period in the example illustrated in FIG. 5, the certain period is not particularly limited as long as it is the 1H period or longer. With this configuration, it is possible to wait for the fluctuation of the voltage of electrode piece 12b to subside and reduce noise generation.

On the basis of the horizontal synchronization signal Hss, signals from the unit pixel cells 10 belonging to each row of the pixel array PA are read out. In this example, starting at time t15, signals from the unit pixel cells 10 belonging to rows R0 to R7 are sequentially read out on a row-by-row basis. Hereinafter, the period between the selection of unit pixel cells 10 belonging to a row and the re-selection of unit pixel cells 10 belonging to that row is sometimes referred to as “1V period.”

In this example, the period from time t0 to time t15 corresponds to the 1V period. After the end of the exposure period, the address transistor 26 in row R0 is turned on when the signal is read from the unit pixel cells 10 in row R0. As a result, the pixel signal corresponding to the amount of charge accumulated in the charge accumulation region during the exposure period is output to the vertical signal line 47. Following the pixel signal readout, the reset transistor 28 is turned on to reset the unit pixel cells 10. After the reset, the reset transistor 28 is turned off again. Then, the signal (i.e., reset signal) after the reset transistor 28 is turned off is read out. After reading the reset signal, the address transistor 26 is turned off. By taking the difference between the pixel signal from the unit pixel cells 10 belonging to each row of the pixel array PA and the reset signal, it is possible to obtain a signal from which fixed noise is removed.

In the non-exposure period, the voltage V3 is applied to the electrode piece 12b of the counter electrode 12, and therefore the photoelectric conversion layer 15 of the photoelectric conversion unit 13 has the bias voltage of the third voltage range applied thereto. Therefore, even when light is incident on the photoelectric conversion layer 15, there is substantially no further accumulation of signal charge in the charge accumulation region. Accordingly, generation of noise caused by unintentional charge contamination is reduced.

Note that from the viewpoint of reducing further accumulation of signal charge in the charge accumulation region, it is also conceivable to end the exposure period by applying a voltage to the counter electrode 12 that reverses the polarity of the voltage Ve described above. However, simply reversing the polarity of the voltage applied to the counter electrode 12 can cause transfer of the already accumulated signal charge to the counter electrode 12 via the photoelectric conversion layer 15. Transfer of the signal charge from the charge accumulation region to the counter electrode 12 via the photoelectric conversion layer 15 is observed, for example, as a black spot in the acquired image. That is, the transfer of the signal charge from the charge accumulation region to the counter electrode 12 via the photoelectric conversion layer 15 can be a factor of negative parasitic sensitivity.

In this example, the voltage applied to counter electrode 12 is changed to the voltage V3 again after the exposure period is over, so that the photoelectric conversion layer 15 after the accumulation of the signal charge in the charge accumulation region is ended has the bias voltage of the third voltage range applied thereto. With the bias voltage of the third voltage range applied, it is possible to reduce the transfer of the signal charge already accumulated in the charge accumulation region to the counter electrode 12 via the photoelectric conversion layer 15. In other words, by applying the bias voltage of the third voltage range to the photoelectric conversion layer 15, the signal charge accumulated during the exposure period can be retained in the charge accumulation region. That is, negative parasitic sensitivity due to loss of signal charge from the charge accumulation region can be reduced.

As has been described, in the present embodiment, the start and end of the exposure period for each row is controlled for each row by the bias voltage applied to the electrode piece 12b of the counter electrode 12. That is, according to the present embodiment, the adjustment function of the exposure period can be achieved without turning on the reset transistor 28 in each unit pixel cell 10. For example, a non-exposure period can be provided after a reset operation and before the start of an exposure period, as in the period from time t1 to time t2 in row R0 of FIG. 5. In the present embodiment, since the shutter operation is performed by controlling the bias voltage without resetting the signal charge via reset transistor 28, faster operation is possible. It is also advantageous for low power consumption because the reset operation and the noise cancellation operation which define the start of an exposure period are unnecessary.

In the present embodiment, during a period for the unit pixel cells 10 belonging to a first pixel block of pixel blocks 10b to output signals to the vertical signal line 47, the voltage supply circuit 32 does not change the bias voltage applied to the electrode piece 12b of the counter electrode 12 of a second pixel block adjacent to the first pixel block of the pixel blocks 10b. For example, if the first pixel block is a pixel block formed of unit pixel cells 10 belonging to row R1, the second pixel block is a pixel block formed of unit pixel cells 10 belonging to row R0.

In FIG. 5, signal readout is performed for the unit pixel cells 10 in row R1 adjacent to row R0 (i.e., unit pixel cells 10 belonging to the first pixel block) during a 1H period from time t1 to time t2. Hence, if the bias voltage of the electrode piece 12b of the unit pixel cells 10 in row R0 is changed before the end of this period, noise may be generated when reading out signals from the unit pixel cells 10 in row R1. In the present embodiment, the unit pixel cells 10 in row R0 (i.e., unit pixel cells 10 belonging to the second pixel block) start the exposure period at time t2 after a 1H non-exposure period after the end of the readout period at time t1. This reduces the effect of the signal readout operation on the unit pixel cells 10 in the adjacent row R1.

Moreover, in the present embodiment, the length of the exposure period may be adjusted by the end of the exposure period, i.e., at the timing when the bias voltage applied to the electrode piece 12b is changed from the voltage Ve to the voltage V3. Also, the length of the period between the end of the exposure period and the signal readout may be set longer than the period between the readout of the previous frame period and the start of the exposure period. This allows signal detection after the signal charge state in the photoelectric conversion layer 15 has stabilized sufficiently after the end of the exposure period, thus enabling high-quality imaging data to be obtained.

### Embodiment 2

Subsequently, Embodiment 2 will be described.

An imaging device according to Embodiment 2 is different from Embodiment 1 in the number of rows of unit pixel cells included in a pixel block. Hereinafter, the description will be given mainly on the differences from Embodiment 1 and description of common points will be omitted or simplified.

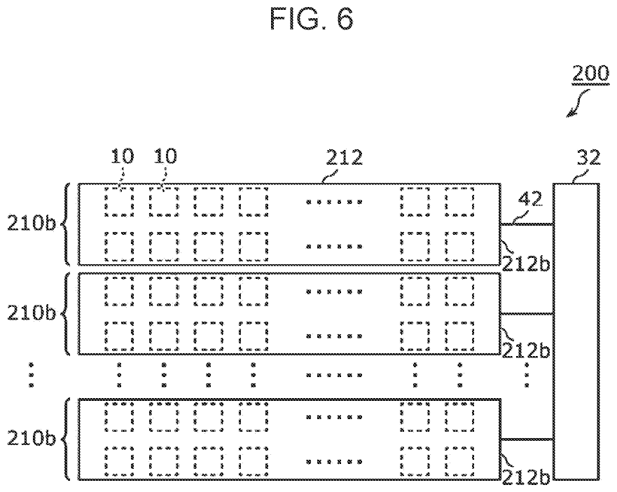

FIG. 6 is a schematic plan view illustrating the relationship between a unit pixel cell 10 and a counter electrode 212 of an imaging device 200 according to the present embodiment. In the present embodiment, unit pixel cells 10 form pixel blocks 210b each including i or more rows. Here, i is an integer of 2 or more. In the example illustrated in FIG. 6, i=2. Each of the pixel blocks 210b includes two adjacent rows of unit pixel cells 10. While an example of a case where i=2 will be described below, i may be 3 or more.

The counter electrode 212 according to the present embodiment is separated by every i row. Specifically, the counter electrodes 212 have electrode pieces 212b corresponding one-to-one with the pixel blocks 210b. As illustrated in FIG. 6, the electrode pieces 212b are provided every two rows and are separated from each other. That is, the electrode piece 212b covers a pixel electrode 11 of each of the unit pixel cells 10 belonging to the same two rows.

As in Embodiment 1, a voltage supply circuit 32 can control the magnitude and timing of the voltage applied for each electrode piece 212b. With this configuration, it is possible to control, for each pixel block 210B, the state of the unit pixel cells 10 belonging to the corresponding pixel block 210B.

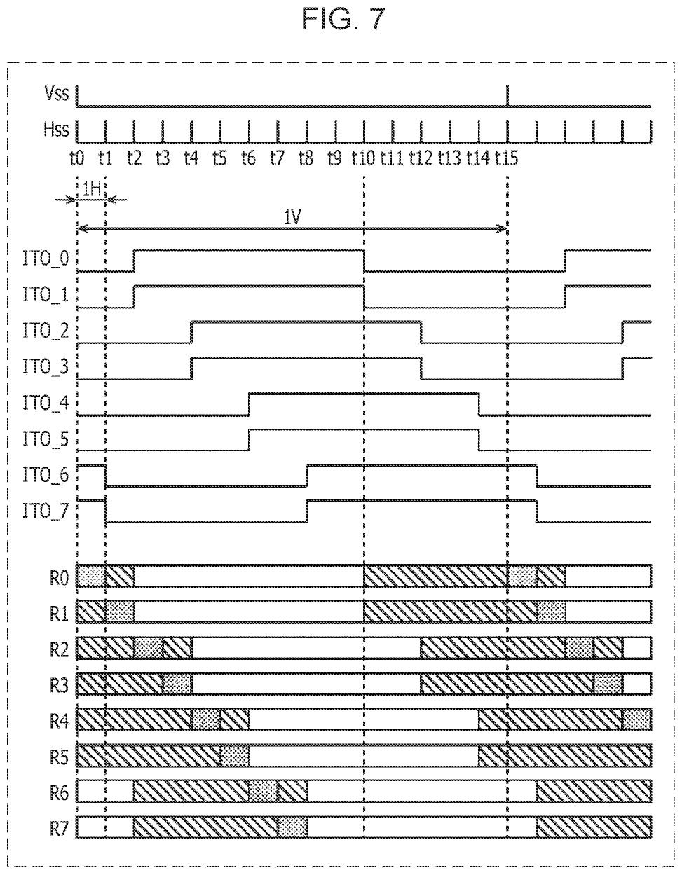

FIG. 7 is a diagram for describing an example of the operation of the imaging device 200 according to the present embodiment. In the present embodiment, since the electrode piece 212b of the counter electrode 212 is provided across two rows, control of the start and end of the exposure period is done every two rows. For example, as illustrated in FIG. 7, ITO_0 and IT0_1 corresponding to rows R0 and R1, respectively, indicate the temporal change of the bias voltage applied to one electrode piece 212b. The start and end timing of the exposure period for two adjacent rows of unit pixel cells 10 are the same. For each pixel block 210b, exposure periods start and end sequentially at different times.

In the present embodiment, the signals are read out sequentially at different timings for each line, as in Embodiment 1. Specifically, signal readout, reset, and reset readout from the unit pixel cells 10 belonging to row R0 are performed in the period from time t0 to time t1, and then signal readout, reset, and reset readout from the unit pixel cells 10 belonging to row R1 are performed in the period from time t1 to time t2.

As has been described, in the imaging device 200 according to the present embodiment, unit pixel cells 10 form the pixel block 210b for each of two or more rows, and the counter electrode 212 is provided separately for each pixel block 210b. That is, the counter electrode 212 has the electrode piece 212b provided across two or more rows.

With this configuration, it is possible to reduce the number of electrode pieces 212b of the counter electrode 212, and reduce number of buffer circuits required to drive the electrode piece 212b. For example, it is sufficient that one buffer circuit be provided for each electrode piece 212b. The machining accuracy to form electrode pieces 212b need not be high.

Since the line width (i.e., the length in the row direction) of electrode piece 212b is wider, the resistance of the electrode piece 212b is lower. Additionally, the parasitic capacitance of the electrode piece 212b could be reduced. From these, if the resistance of the electrode piece 212b is R and the parasitic capacitance of the electrode piece 212b is C, the time constant of settling of the electrode piece 212b is expressed by RC. This may reduce the settling time constant of the electrode piece 212b and shorten the settling period.

### Embodiment 3

Subsequently, Embodiment 3 will be described.

An imaging device according to Embodiment 3 is different from Embodiment 1 in that the bias voltage applied to the electrode piece is varied during the exposure period and the non-exposure period. The configuration of the imaging device is the same as that of the imaging device 100 according to Embodiment 1 described with reference to FIGS. 1 to 3. Hereinafter, using the configuration of the imaging device 100, the description will be given mainly on the differences from Embodiment 1 and description of common points will be omitted or simplified.

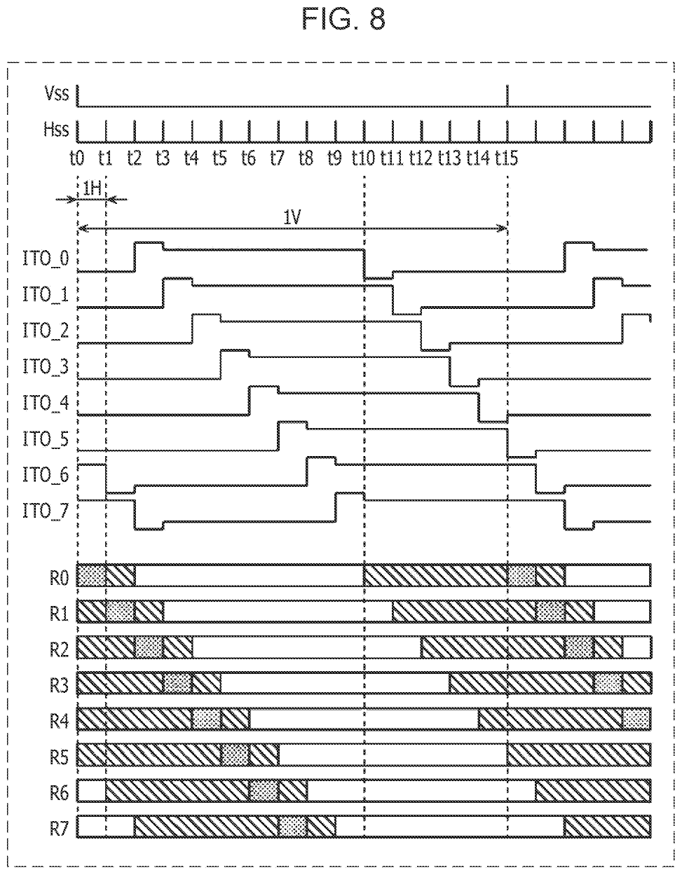

FIG. 8 is a diagram for describing an example of the operation of an imaging device 100 according to the present embodiment. In the present embodiment, a voltage supply circuit 32 changes the voltage value of the bias voltage to two or more values during the exposure period. For example, the voltage supply circuit 32 temporarily increases the bias voltage at the starting time point of the exposure period.

For example, in FIG. 8, focus on an electrode piece 12b of ITO_0 corresponding to row R0. The voltage value of the bias voltage applied to the electrode piece 12b during the period from time t2 to time t3 at the start of the exposure period is higher than the voltage value of the bias voltage applied during the period from time t3 to time t10. This can shorten the period until the bias voltage stabilizes, thus speeding up the operation of the imaging device 100.

Additionally, the voltage supply circuit 32 changes the voltage value of the bias voltage to two or more values during the non-exposure period. For example, the voltage supply circuit 32 temporarily lowers the bias voltage at the starting time point of the non-exposure period.

For example, in FIG. 8, focus on the electrode piece 12b of ITO_0 corresponding to row R0. During the period from time t10 to time t11 at the start of the non-exposure period, the voltage value of the bias voltage applied to electrode piece 12b is lower than the voltage value of the bias voltage applied during the period from time t0 to time t2 and from time t11 to time t15. This can shorten the period until the bias voltage stabilizes, thus speeding up the operation of the imaging device 100.

Note that while FIG. 8 illustrates an example in which the period during which the bias voltage is increased at the starting time point of the exposure period is a 1H period, the period may be shorter than the 1H period or a 2H period or longer. The same applies to the period during which the bias voltage is lowered at the starting time point of the non-exposure period. It is also possible to provide the period during which the bias voltage is changed to two or more values for only one of the exposure period and the non-exposure period.

For example, the voltage value of the bias voltage may be changed to two or more values at timings and periods other than the starting time point of the exposure period or non-exposure period. This can also change the sensitivity per unit time, whereby sensitivity can be fine-tuned. It can also expand the dynamic range.

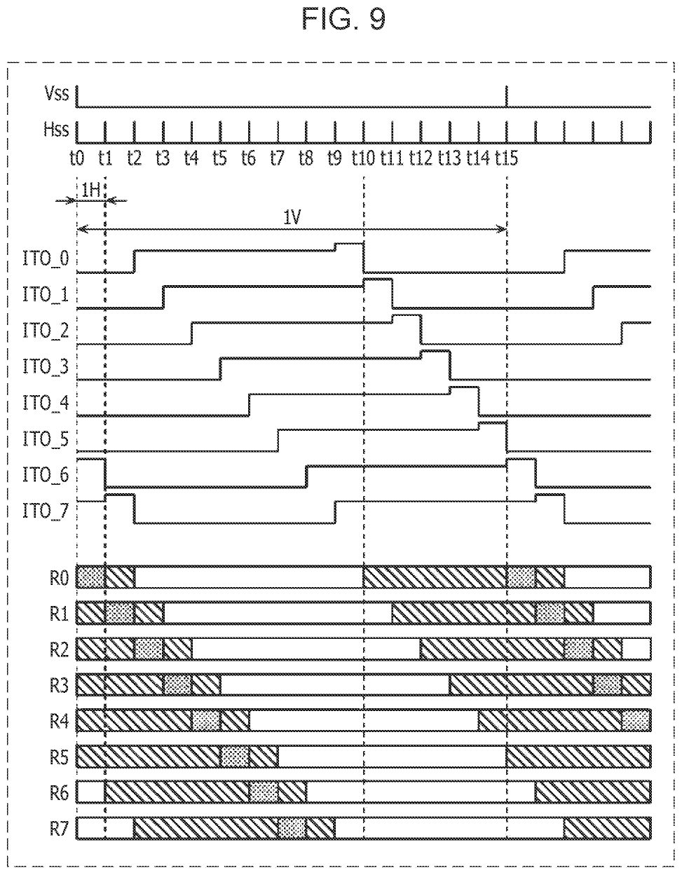

FIG. 9 is a diagram for describing an example of the operation of the imaging device 100 according to the present embodiment. In the example illustrated in FIG. 9, the voltage supply circuit 32, for example, sets the voltage value of the bias voltage in the period immediately before the end of the exposure period higher than the voltage value in the other periods. For example, in FIG. 9, focus on the electrode piece 12b of ITO_0 corresponding to row R0. The voltage value of the bias voltage applied to the electrode piece 12b during the period from time t9 to time t10 immediately before the end of the exposure period is higher than the voltage value of the bias voltage applied during the period from time t2 to time t9. This allows the sensitivity of the period from time t9 to time t10 to be higher than the sensitivity of the other periods. In this case, an image with an afterimage effect can be obtained for a subject in motion.

Note that while FIG. 9 illustrates an example in which the period of increasing the bias voltage immediately before the end of the exposure period is the 1H period, the period may be shorter than the 1H period or the 2H period or longer. The bias voltage may be lowered immediately before the end of the exposure period. Instead of immediately before the end of the exposure period, the bias voltage may be increased or decreased immediately after the start of the exposure period or during a certain period in the middle of the exposure period.

The control illustrated in FIG. 8 or 9 can also be applied to the imaging device 200 according to Embodiment 2.

### Embodiment 4

Subsequently, Embodiment 4 will be described.

An imaging device according to Embodiment 4 is different from Embodiment 1 in that a non-exposure period is provided in the middle of an exposure period. In other words, two or more exposure periods are provided in one frame period. The configuration of the imaging device according to the present embodiment is the same as that of the imaging device 100 according to Embodiment 1 described with reference to FIGS. 1 to 3. Hereinafter, using the configuration of the imaging device 100, the description will be given mainly on the differences from Embodiment 1 and description of common points will be omitted.

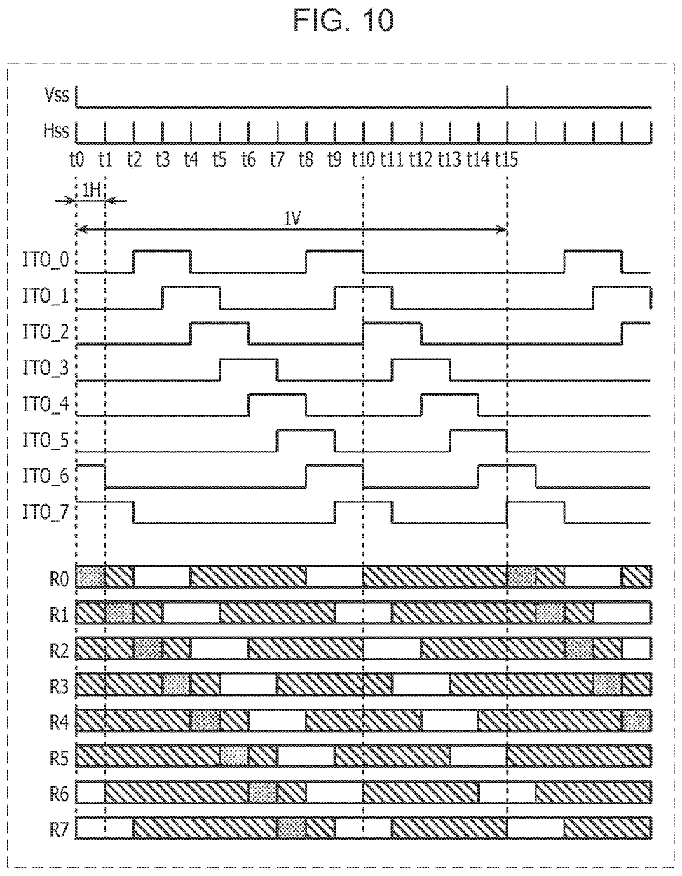

FIG. 10 is a diagram for describing an example of the operation of the imaging device 100 according to the embodiment. In the present embodiment, the voltage supply circuit 32 performs two or more shutter operations within one frame period.

For example, in FIG. 10, focus on row R0. The exposure period includes a first period from time t2 to time t4 and a second period from time t8 to time t10. The period between the first and second periods is a non-exposure period, but no signal readout or reset is performed during this period. That is, the signal charge accumulated by the exposure in the first period is retained as it is in the charge accumulation region during the non-exposure period between the first and second periods, and additional signal charge is retained by the exposure in the second period.

In the present embodiment, it is possible to add the second period. For example, if sufficient signal charge cannot be obtained only by exposure during the first period, such as when the light amount of the incident light is small, a sufficient signal charge can be obtained by adding a second period, so that image quality can be enhanced. Such an operation is effective when the period between immediately after signal readout and the start of the first period of exposure is short.

As has been described, according to the imaging device 100 according to the present embodiment, the length of the exposure period can be changed in the middle of one frame period. For example, even if a short exposure period is set in a frame, the exposure period can be extended in the middle of the frame period. For example, this is useful if an exposure period needs to be added in the middle of a frame period on the basis of the imaging data of the previous frame.

Note that the vertical synchronization signal Vss often triggers the start of a signal readout. In such a case, the starting time point of the exposure period may be set by regarding immediately after the start of the signal readout as the reference point. This facilitates control of the exposure period. For example, if the reference point is immediately before the signal readout, it is necessary to calculate the starting time point of the signal readout. In contrast, if the reference point is immediately after the start of the signal readout, a new signal for which exposure can be controlled can be driven after the end of the exposure period within the 1V period, as in the present embodiment.

While the lengths of the first and second periods are the same in the example illustrated in FIG. 10, the lengths may be different. The exposure period may include three or more periods. The lengths of the non-exposure periods between the periods may be the same or may be different.

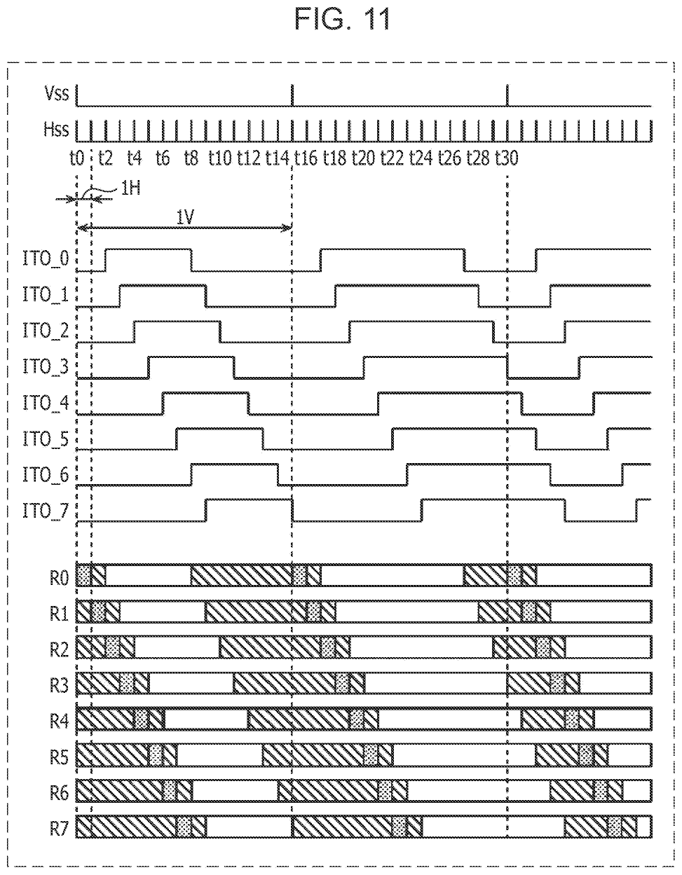

For example, the exposure period may be changed on a frame-by-frame basis. FIG. 11 is a diagram for describing another example of the operation of the imaging device 100 according to the present embodiment. In FIG. 11, focusing on row R0, the exposure period in the first frame period from time t0 to time t15 is a 6H period from time t2 to time t8. Meanwhile, the exposure period in the second frame period from time t15 to time t30 is a 10H period from time t17 to time t27. Thus, the exposure period may be changed for different frame periods. For example, this allows an appropriate exposure period to be set according to the amount of incoming light, thereby enhancing image quality.

Note that the exposure period may be different for each pixel block. For example, the exposure period may be set longer for a pixel block with a smaller amount of light than for a pixel block with a larger amount of light. As a result, it is possible to obtain images with less partial white skipping or block up. For example, a pixel block with a long exposure period and a pixel block with a short exposure period may be mixed, and signals from pixels of each pixel block may be combined. As a result, an image with an expanded dynamic range can be obtained.

The control illustrated in FIG. 10 or 11 can also be applied to the imaging device 200 according to Embodiment 2.

### Embodiment 5

Subsequently, Embodiment 5 will be described.

An imaging device according to Embodiment 5 is different from Embodiment 2 in including two or more vertical signal lines for each column. Hereinafter, the description will be given mainly on the differences from Embodiment 2 and description of common points will be omitted or simplified.

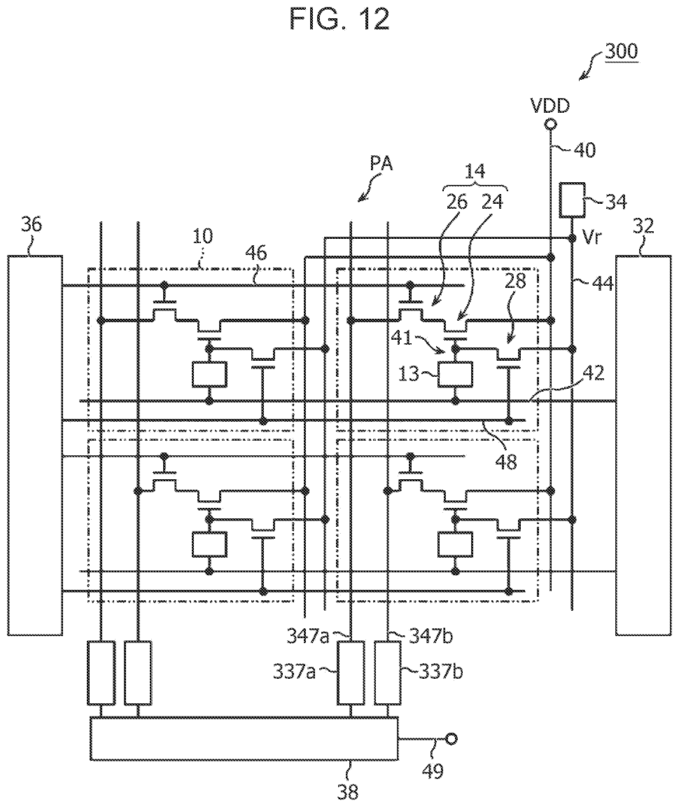

FIG. 12 is a schematic diagram illustrating an exemplary circuit configuration of an imaging device 300 according to the present embodiment. In the imaging device 300, as in the imaging device 200 according to Embodiment 2, a counter electrode 212 is separated by every i rows. While an example of a case where i=2 will be described below, i may be 3 or more.

In the present embodiment, the imaging device 300 has j vertical signal lines for each column. j is an integer of 2 or more and i or less. As illustrated in FIG. 12, the imaging device 300 includes two vertical signal lines 347a and 347b. The two vertical signal lines 347a and 347b are provided for each column. The vertical signal line 347a is connected to unit pixel cells 10 belonging to odd-numbered rows, for example. The vertical signal line 347b is connected to unit pixel cells 10 belonging to odd-numbered rows, for example.

Each of the vertical signal lines 347a and 347b is connected to column signal processing circuits 337a and 337b. The column signal processing circuits 337a and 337b are the same as the column signal processing circuit 37 according to Embodiment 1.

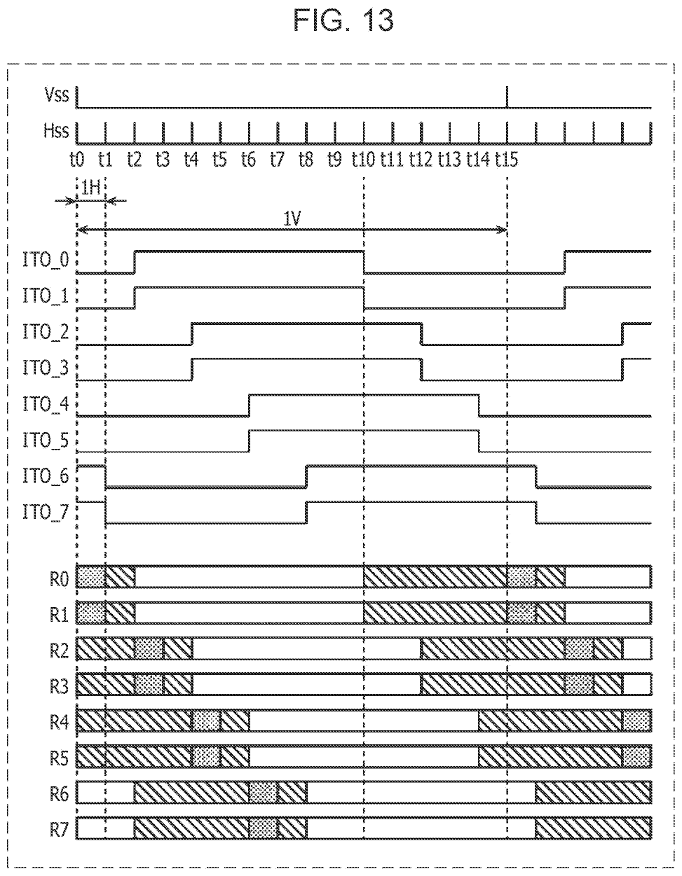

As has been described, by providing j vertical signal lines, signals from j rows of unit pixel cells 10 can be read out simultaneously. FIG. 13 is a diagram for describing an example of the operation of the imaging device 300 according to the present embodiment. As illustrated in FIG. 13, the control of the bias voltage to a counter electrode 212 is the same as Embodiment 2. In the present embodiment, two vertical signal lines are provided so that signals can be read out simultaneously from two adjacent rows of unit pixel cells 10.

Note that the vertical signal line 347a is connected to the unit pixel cells 10 of rows R0, R2, R4, and R6, for example. The vertical signal line 347b is connected to the unit pixel cells 10 of rows R1, R3, R5, and R7, for example.

With this configuration, it is possible to improve the signal readout speed and thus the imaging speed.

### Embodiment 6

Subsequently, Embodiment 6 will be described.

Embodiment 6 is an imaging system including the imaging device according to the above embodiments. Hereinafter, the description will be given mainly on the differences from the above embodiments and description of common points will be omitted or simplified.

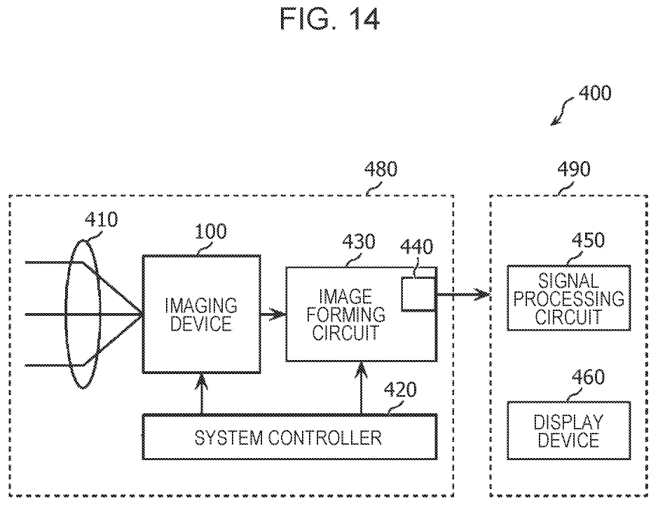

FIG. 14 is a block diagram illustrating an example of an imaging system 400 according to the present embodiment. The imaging system 400 illustrated in FIG. 14 generally has a camera unit 480 and a display unit 490. The camera unit 480 and the display unit 490 may be two parts of a single device, or may each be a separate and independent device. As illustrated in FIG. 14, the camera unit 480 includes an optical system 410, an imaging device 100, a system controller 420, and image forming circuit 430. The display unit 490 includes a signal processing circuit 450 and a display device 460.

The optical system 410 includes an aperture, an image stabilization lens, a zoom lens, a focus lens, and the like. The number of lenses that the optical system 410 has is appropriately determined according to the required functionality.

The system controller 420 controls each processing unit included in the camera unit 480. The system controller 420 is a semiconductor integrated circuit, such as a central processing unit (CPU), that sends control signals to a lens drive circuit in the optical system 410, for example. In this example, the system controller 420 also controls the operation of the imaging device 100. For example, the system controller 420 controls driving of a vertical scan circuit 36. Switching of the voltage applied from a voltage supply circuit 32 to a sensitivity control line 42 may be performed on the basis of the control of the system controller 420. The system controller 420 may include one or more memories.

The image forming circuit 430 forms an image on the basis of the output of the imaging device 100. The image forming circuit 430 can be, for example, a digital signal processor (DSP), a field-programmable gate array (FPGA), or the like. The image forming circuit 430 may include a memory.

In the example illustrated in FIG. 14, the image forming circuit 430 has an output buffer 440. The image forming circuit 430 outputs the generated image data to the display unit 490 via the output buffer 440. The data output from the image forming circuit 430 is typically RAW data, such as a 12-bit wide signal. The data output from the image forming circuit 430 may be data compressed in accordance with the H.264 standard, for example.

The signal processing circuit 450 of the display unit 490 receives output from the image forming circuit 430. The output from the image forming circuit 430 may be stored once in an external recording medium (e.g., flash memory device) freely connectable to and removable from the camera unit 480. That is, the output from the image forming circuit 430 may be passed to the display unit 490 via an external recording medium.

The signal processing circuit 450 performs processing such as gamma correction, color interpolation, spatial interpolation, and auto white balance. The signal processing circuit 450 is typically a DSP, an image signal processor (ISP), or the like.

The display device 460 is a liquid crystal display, an organic electroluminescence (EL) display, or the like. The display device 460 displays images on the basis of output signals from the signal processing circuit 450. The display unit 490 can be a personal computer, a smartphone, or the like.

Note that while FIG. 14 illustrates an example of the imaging system 400 including the imaging device 100, the imaging system 400 may include the imaging device 200 or 300.

### Other Embodiments

While the description of the imaging device according to one or more aspects has been given on the basis of the embodiments, the present disclosure is not limited to these embodiments. Variations conceived of by those skilled in the art and modes constructed by combining components of different embodiments are also included within the scope of this disclosure without departing from the gist of the present disclosure.

For example, while each transistor in the imaging device is an N-channel MOSFET in the example, a P-channel MOSFET can be used instead. Each transistor may be a FET other than a MOSFET, and may be a bipolar transistor. In the case where each transistor is a bipolar transistor, the gate, source, and drain are replaced by the base, emitter, and collector, respectively, in the above description.

In addition, in each of the above embodiments changes, replacements, additions, omissions, and the like can be made in various ways within the scope of the claims or their equivalents.

The imaging device of the present disclosure is applicable to an image sensor, for example. The imaging device of the present disclosure can be used for a digital camera, a medical camera, a camera for a robot, or the like.

What is claimed is:

1. An imaging device comprising:
pixels arranged in rows and columns, and
a voltage supply circuit, wherein:
each of the pixels includes
a pixel electrode,
a counter electrode facing the pixel electrode,
a photoelectric conversion layer located between the pixel electrode and the counter electrode, the photoelectric conversion layer converting light into signal charge, and
a charge accumulation region electrically connected to the pixel electrode, the charge accumulation region accumulating the signal charge;
the pixels form pixel blocks each including one or more rows;
the counter electrode is continuous between pixels in each pixel block and separated between different pixel blocks; and
the voltage supply circuit sequentially performs a shutter operation on the pixel blocks at different timings, the shutter operation forming an exposure period by applying a first voltage to the counter electrode and forming a non-exposure period by applying a second voltage to the counter electrode.

2. The imaging device according to claim 1, wherein
each pixel block includes pixels belonging to a row.

3. The imaging device according to claim 1, wherein
each pixel block includes pixels belonging to two or more rows.

4. The imaging device according to claim 1, wherein
a length of the exposure period in a first frame period is different from a length of the exposure period in a second frame period different from the first frame period.

5. The imaging device according to claim 1, wherein
the voltage supply circuit changes a voltage value of the first voltage to two or more values in the exposure period.

6. The imaging device according to claim 1, wherein
the voltage supply circuit changes a voltage value of the second voltage to two or more values in the non-exposure period.

7. The imaging device according to claim 1, further comprising
output signal lines to which signals from the pixels are input, wherein
the output signal lines are arranged for each column.

8. The imaging device according to claim 1, further comprising
output signal lines to which signals from the pixels are input, wherein
the voltage supply circuit does not change a voltage applied to the counter electrode of a second pixel block adjacent to a first pixel block of the pixel blocks in a period for pixels belonging to the first pixel block to output a signal to the output signal lines.

9. The imaging device according to claim 1, wherein
the voltage supply circuit performs the shutter operation two or more times within one frame period.
